(19) United States
(12) Patent Application Publication
(10) Pub. No.: US 2025/0227938 A1
(43) Pub. Date: Jul. 10, 2025

(54) Semiconductor layout pattern including high-voltage device, and semiconductor structure including high-voltage device

(71) Applicant: UNITED MICROELECTRONICS CORP., Hsin-Chu City (TW)

(72) Inventors: Hung-Chan Lin, Tainan City (TW); Kuo-Hsing Lee, Hsinchu County (TW); Chang-Yih Chen, Tainan City (TW); Chun-Hsien Lin, Tainan City (TW)

(73) Assignee: UNITED MICROELECTRONICS CORP., Hsin-Chu City (TW)

(21) Appl. No.: 18/424,896

(22) Filed: Jan. 29, 2024

(30) Foreign Application Priority Data
Jan. 5, 2024 (TW) 113100592

(51) Int. Cl. H10B 61/00; H01L 23/552

(52) U.S. Cl. CPC H10B 61/22; H01L 23/552

(57) ABSTRACT

The invention provides a semiconductor layout pattern including high-voltage devices, which comprises a substrate, wherein a high-voltage device region and an MRAM (magnetic random access memory) region are adjacent to each other, wherein the MRAM region at least comprises a plurality of MRAM cells arranged in an array, wherein each MRAM cell comprises two fin structures parallel to each other and arranged along an X direction, and two gate structures parallel to each other and arranged along a Y direction. A drain metal layer is located between the two gate structures, two source metal layers are located on the other side of the two gate structures, respectively, and an MTJ (magnetic tunneling junction) element is electrically connected with the drain metal layers.

### BACKGROUND OF THE INVENTION

### 1. Field of the Invention

The present invention relates to the field of semiconductors, in particular to a semiconductor layout pattern including high-voltage devices and integrating the high-voltage devices with magnetic random access memory (MRAM), and a semiconductor structure with shielding structure.

### 2. Description of the Prior Art

Display RAM is a kind of memory specially used for storing images or image data. It is usually used in monitors or display cards to access and display image data quickly. Different from other types of memory, display memory needs to have high-speed reading and writing ability in order to update the image of the display quickly. In addition, display memory usually needs to have high density and low power consumption, so that it can store more image data in a smaller area.

Display memory is usually a volatile memory, which means that it needs continuous power supply to keep its stored data. If the power supply is interrupted, data will be lost. Therefore, the display memory usually needs to be equipped with batteries or other backup power sources in order to maintain data integrity when power is cut off. In terms of specifications, the display memory needs to have enough capacity to store the image data of the whole display screen. It also needs to have enough broadband and speed so that it can read and write a large amount of data quickly.

Magnetic random access memory (MRAM) is a nonvolatile memory technology, which uses magnetization state to represent stored data. Generally speaking, MRAM includes a plurality of magnetic storage cell bits in an array. Each storage unit basically represents a bit value of data. The storage unit includes at least one magnetic element, which can include two magnetic plates (or material layers on a semiconductor substrate) with a magnetic direction (or bit direction of magnetic moment) related to them, and a thin nonmagnetic layer is also included between the two magnetic plates.

More specifically, an MRAM device is usually based on a magnetic tunnel junction (MTJ) element. An MTJ element includes at least three basic layers: a free layer, an insulating layer, and a fixed layer. Wherein the free layer and the fixed layer are magnetic layers, and the insulating layer is an insulating layer, which is located between the free layer and the fixed layer. In addition, the magnetization direction of the free layer can rotate freely, but it is limited by the physical size of the layer and only points to one of two directions (parallel or antiparallel to the magnetic direction of the fixed layer). The magnetization direction of the fixed layer is fixed in a specific direction. A bit is written in one of the above two directions by locating the magnetization direction of the free layer. Depending on the same or opposite directions of the magnetic moments of the free layer and the fixed layer, the resistance of the MTJ element will also change. Therefore, the bit value can be read by determining the resistance of the MTJ element. Furthermore, when the magnetization directions of the free layer and the fixed layer are parallel and the magnetic moments have the same polarity, the resistance of the MTJ element is in a low resistance state. Basically, the value stored in this state is represented as “0”. When the magnetization directions of the free layer and the fixed layer are antiparallel and the magnetic moments have opposite polarities, the resistance of the MTJ element is high impedance state. Basically, the value stored in this state is represented as “1”.

### SUMMARY OF THE INVENTION

The invention provides a semiconductor layout pattern including high-voltage devices, which comprises a substrate, wherein a high-voltage device region and an MRAM (magnetic random access memory) region are adjacent to each other, wherein the MRAM region at least comprises a plurality of MRAM cells arranged in an array, wherein each MRAM cell comprises two fin structures which are parallel to each other and arranged along an X direction, and the two gate structures are parallel to each other and arranged along a Y direction. A drain metal layer is located between the two gate structures, two source metal layers are located on the other side of the two gate structures, respectively, and an MTJ (magnetic tunneling junction) element is electrically connected with the drain metal layers.

The invention also provides a semiconductor structure including high-voltage devices, which comprises a substrate, wherein a high-voltage device region and an MRAM (magnetic random access memory) region are adjacent to each other, wherein the MRAM region contains a plurality of fin structures, and at least one MTJ (magnetic tunneling junction) element is located on the plurality of fin structures, and a shielding structure, wherein the shielding structure comprises a horizontal part and a vertical part, and the vertical part is located between the high-voltage device region and the MRAM region.

The invention provides a semiconductor layout pattern including a high-voltage device. The invention is characterized in that a high-voltage device region and an MRAM region are integrated on a chip, wherein the MRAM in the MRAM region is suitable for replacing the display memory in the prior art, and has the advantages of non-volatility, high reading and writing speed, low power consumption and the like, and can greatly improve the performance of a display driving chip. In addition, the MRAM region of the present invention further makes the element on the fin structure to form a three-dimensional element, so that the element area can be further reduced and the element density can be improved. However, since the high-voltage device region and the MRAM region are integrated on the same chip at the same time, in order to prevent the high-voltage device from generating strong electromagnetic waves to affect the operation efficiency of the device in the MRAM region, another embodiment of the present invention provides a shielding structure, in which the shielding structure has a special shape (the horizontal part is a mesh and the vertical part is a fence), which has the advantages of shielding electromagnetic waves and improving the product yield.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 shows a schematic diagram of the connection relationship between elements of a semiconductor structure including an MRAM structure.

FIG. 2 shows a top view of a fin structure, a gate structure, a drain metal layer, a source metal layer, a contact structure and a first metal layer in a semiconductor layout of the present invention.

FIG. 3 shows a top view of the first metal layer and the first contact plug in the semiconductor layout of the present invention.

FIG. 4 shows a top view of the first contact plug and the second metal layer in the semiconductor layout of the present invention.

FIG. 5 shows a top view of the second metal layer and the MTJ element in the semiconductor layout of the present invention.

FIG. 6 shows a top view of the MTJ element and the third metal layer in the semiconductor layout of the present invention.

FIG. 7 shows a top view of a shielding structure in a semiconductor structure of the present invention.

FIG. 8 is a perspective view of the shielding structure in the semiconductor structure of the present invention.

FIG. 9 is a schematic cross-sectional view of the shielding structure and MRAM structure in the semiconductor structure of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

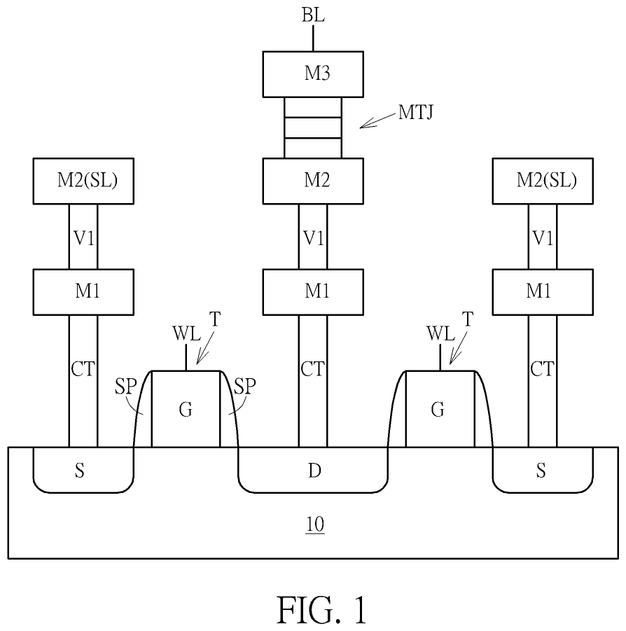

Please refer to FIG. 1, which shows a schematic diagram of the connection relationship between elements of a semiconductor structure including an MRAM structure. First, a substrate 10 includes at least one transistor T, wherein the transistor T includes a gate structure G, a source S and a drain D. The gate structure G is located on the surface of the substrate 10, and the source S and the drain D are formed in the substrate 10 by ion doping, for example, and are located on both sides of the gate structure G. Both sides of the gate structure G may include spacer SP.

In this embodiment, the drain D of the transistor T is connected to the first metal layer M1, the first contact plug V1, the second metal layer M2 and the magnetic tunneling junction element MTJ (hereinafter referred to as the MTJ element and denoted by the symbol MTJ in the figure) through the contact structure CT, the MTJ element can then be connected to a bit line (BL), and the source S of the transistor T is connected to a selection line (SL) through the contact structure CT, the first contact pillar V1 and the second metal layer M2. The gate structure G of the transistor T can be connected to a word line (WL). It is worth noting that the bit line BL and the word line WL may not directly contact the MTJ element and the gate structure G, but are indirectly electrically connected with the MTJ element and the gate structure G through other metal layers or contact plugs.

In this embodiment, the MTJ element includes a pin layer, an insulating layer and a free layer. The magnetization direction of the free layer can freely rotate and point to one or two directions, and can be switched by using spin-torque transfer (STT). For the fixed layer, an antiferromagnetic layer can be used to fix the magnetization direction in a specific direction. The isolation layer is arranged between the free layer and the fixed layer. As for the first metal layer M1, the second metal layer M2, the third metal layer M3 or the connecting elements such as the contact structure CT and the first contact plug V1, the materials are preferably metals, such as copper and tungsten, but the present invention is not limited to this. The materials and manufacturing methods of the transistor T, the MTJ element or each metal layer or contact structure belong to the prior art in this field, and they will not be repeated here.

As mentioned in the prior art, the current display memory has some disadvantages, for example, it is usually composed of volatile memory, so data will be lost if the power supply is interrupted. In addition, the display memory needs to have enough capacity to store the image data of the whole display screen. It also needs to have enough broadband and speed so that it can read and write a large amount of data quickly.

MRAM is a non-volatile memory, and its reading and writing speed is faster than the components currently used in display memory. Therefore, MRAM is a suitable device to replace the current display memory. If MRAM is used instead of display memory, it can provide better data protection and faster data access speed because of its non-volatile and high-speed reading and writing ability. In addition, MRAM can provide higher density and lower power consumption, so MRAM can store more data in a smaller area while maintaining low power consumption.

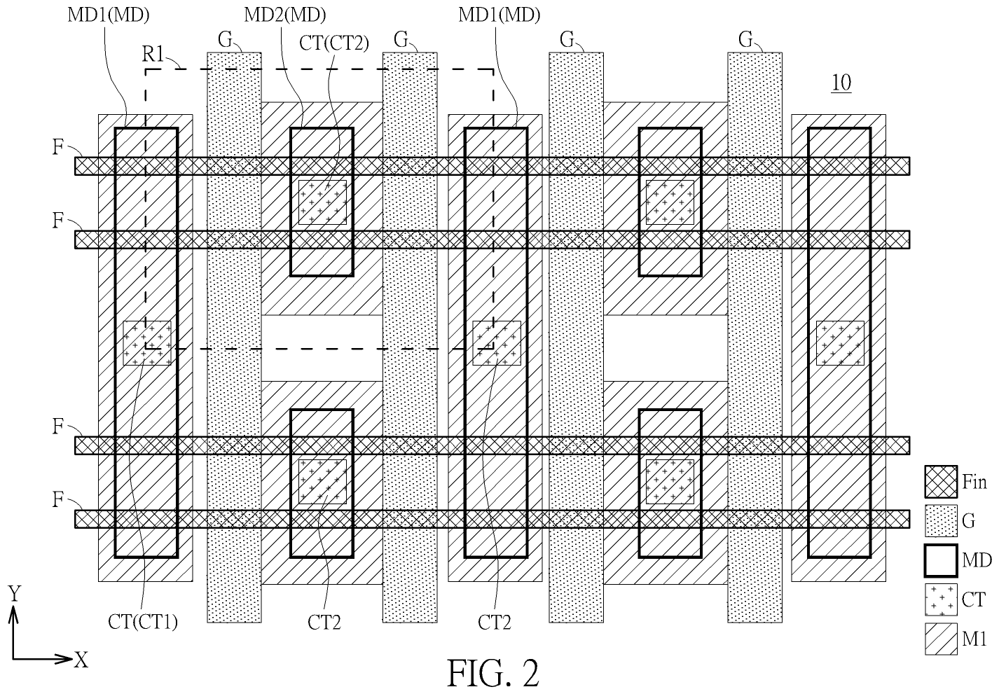

With the development of technology, various semiconductor devices are developing in three dimensions. For example, the semiconductor structure originally made in plane is turned into fin structure to improve the density of components. In order to meet the current technical development requirements, in the first embodiment of the present invention, a semiconductor layout pattern integrating MRAM with fin structure is provided. The invention is characterized in that the high-voltage device region is integrated with an MRAM region on a wafer including high-voltage devices. As mentioned above, the characteristics of MRAM are suitable for integration in high-voltage devices (such as display driving IC), and the MRAM region contains fin structures, that is, each element is formed on the fin structures to realize three-dimensional, so the area of MRAM region can be further reduced. Details are shown in FIGS. 2 to 6 below.

FIG. 2 shows a top view of a fin structure, a gate structure, a drain metal layer, a source metal layer, a contact structure and a first metal layer in a semiconductor layout of the present invention. As shown in FIG. 2, at first, a substrate 10 includes a plurality of fin structures F and a plurality of gate structures G, wherein each fin structure F is arranged in a first direction (for example, X direction) and each gate structure G is arranged in a second direction (for example, Y direction). The gate structure g straddles each fin structure F to form the above transistor T (see also FIG. 1). In addition, in this embodiment, the region R1 is defined first, wherein the region R1 is the region where a single semiconductor cell (including two transistors and an MTJ element) is subsequently formed, which will be described in detail in the following paragraphs.

The substrate 10 further comprises metal layers MD, which comprises a source metal layer MD1 and a drain metal layer MD2, wherein the drain metal layer MD2 is located in the central part of the region R1 and between two adjacent gate structures G, while the source metal layer MD1 is located outside the two gate structures G, that is, on the other side relative to the drain metal layer MD2, and part of the source metal layer MD1 is at the boundary with the region R1 (indicated by dotted lines), that means two adjacent semiconductor cells share a source metal layer MD1.

The source metal layer MD1 and the drain metal layer MD2 straddle the fin structure F to electrically connect the source/drain and other devices formed subsequently, such as selection lines or bit lines. Next, a contact structure CT and a first metal layer M1 are formed on the source metal layer MD1 and the drain metal layer MD2, where the contact structure CT is used to connect the source metal layer MD1 and the drain metal layer MD2 with the first metal layer M1. Please refer to FIG. 1 together. For convenience of distinction, the contact structure on the source metal layer MD1 is defined as the source contact plug CT1, and the contact structure on the drain metal layer MD2 is defined as the drain contact plug CT2.

In the present invention, the source metal layer MD1, the drain metal layer MD2, the contact structure CT, the first metal layer M1 and other metal layers or contact plugs mentioned later are made of conductive materials, such as metals such as tungsten, cobalt, copper, aluminum, gold and silver, but the present invention is not limited to this.

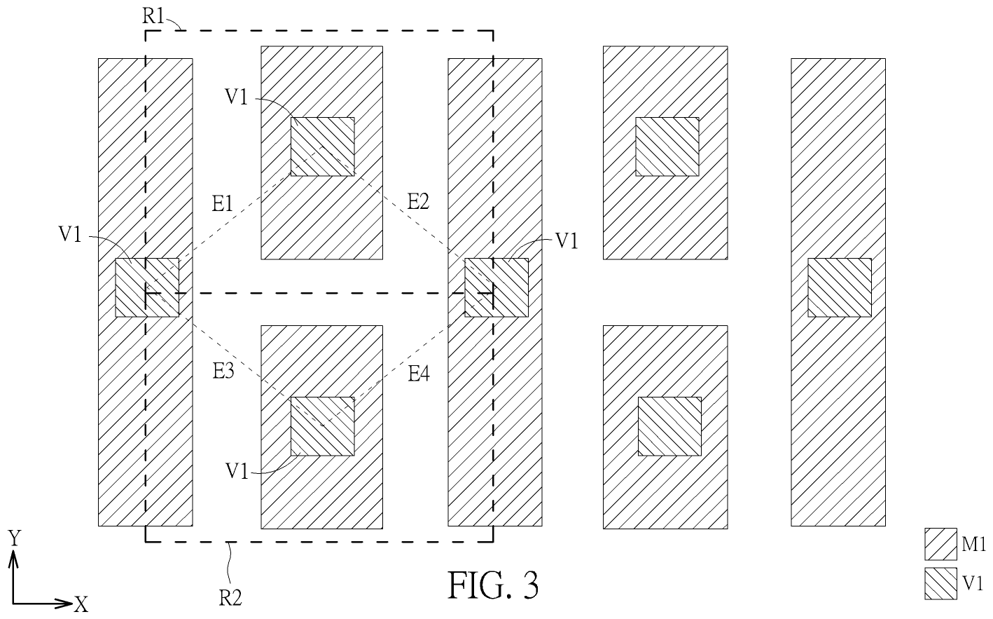

Please refer to FIG. 3, which shows the top view of the first metal layer and the first contact plug in the semiconductor layout of the present invention. Next, continue to form a plurality of first contact plugs V1 on the plane layout pattern shown in FIG. 2. For the sake of simplicity, from FIG. 3 to FIG. 6, when a new pattern layer is formed to cover the old pattern layer, only the uppermost pattern layer in the old pattern layer is drawn, while other lower patterns are omitted. For example, in FIG. 3, only the uppermost first metal layer M1 in FIG. 2 is depicted, and other layers located below, such as fin structures F, gate structures G, contact structures CT, source metal layers MD1 and drain metal layers MD2, are not depicted in FIG. 3. But its relative position can be known by referring to FIG. 2.

In this embodiment, it is worth noting that there are three first contact plugs V1 in the region R1, of which one first contact plug V1 is located above the drain metal layer MD2 and the other two first contact plugs V1 are located above the source metal layer MD1 (please refer to FIG. 2 at the same time). Preferably, the connecting lines of the three first contact plugs V1 present an isosceles triangle. The two sides E1 and E2 of the isosceles triangle have the same length. In addition, two first contact plugs V1 located above the source metal layer MD1 overlap the boundary of the region R1, so that two adjacent semiconductor cells can share the first contact plug V1. For example, FIG. 3 depicts another region R2 adjacent to the region R1 in the Y direction, in which another semiconductor cell is included. After the subsequent process of forming the MTJ, two semiconductor cells located in the region R1 and the region R2 can share the first contact plug V1. In addition, if the region R1 is connected with the four first contact plugs V1 in the region R2, a diamond pattern can be obtained, as shown by the dotted line in FIG. 3, the sides E1, E2, E3 and E4 of the diamond are equal in length.

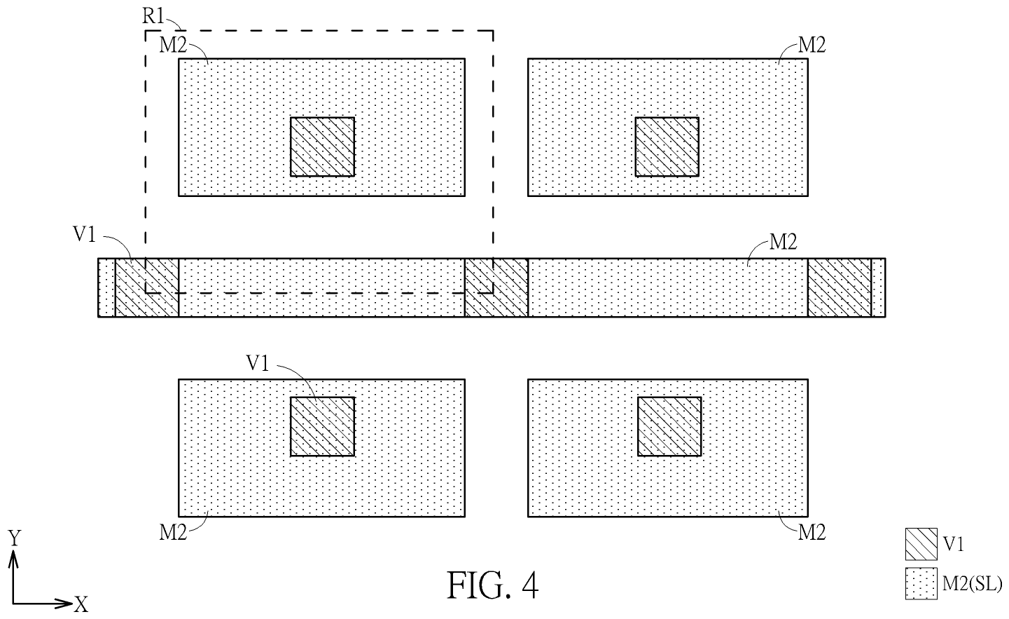

Please refer to FIG. 4, which shows the top view of the first contact plug and the second metal layer in the semiconductor layout of the present invention. Next, as shown in FIG. 4, the second metal layer M2 is continuously formed. It is worth noting that because the first contact plugs V1 located on the source metal layer MD1 are aligned along the X direction, a part of the second metal layer M2 also extends along the X direction and connects the first contact plugs V1 located on the source metal layer MD1, and this second metal layer extending along the X direction can be connected with the selection line SL (refer to FIG. 1). Therefore, the arrangement of the first contact plug V1 of the present invention only needs one second metal layer M2 extending along the X direction to connect the sources of adjacent semiconductor cells to the selection line SL, which has the advantage of simplifying the pattern.

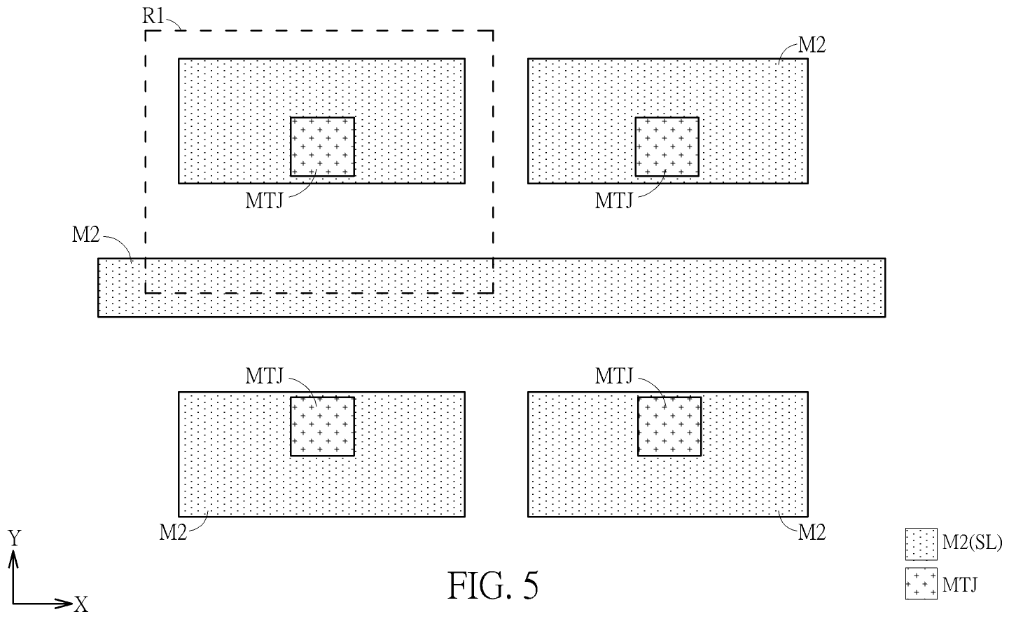

Please refer to FIG. 5, which shows the top view of the second metal layer and the MTJ element in the semiconductor layout of the present invention. As shown in FIG. 5, the MTJ element is continuously formed on the second metal layer M2. Among them, structures such as tungsten contact plugs may be included between the MTJ element and the second metal layer M2, which are not shown here for the sake of simplicity. Other characteristics of MTJ elements belong to the known technology in this field, and they will not be repeated here.

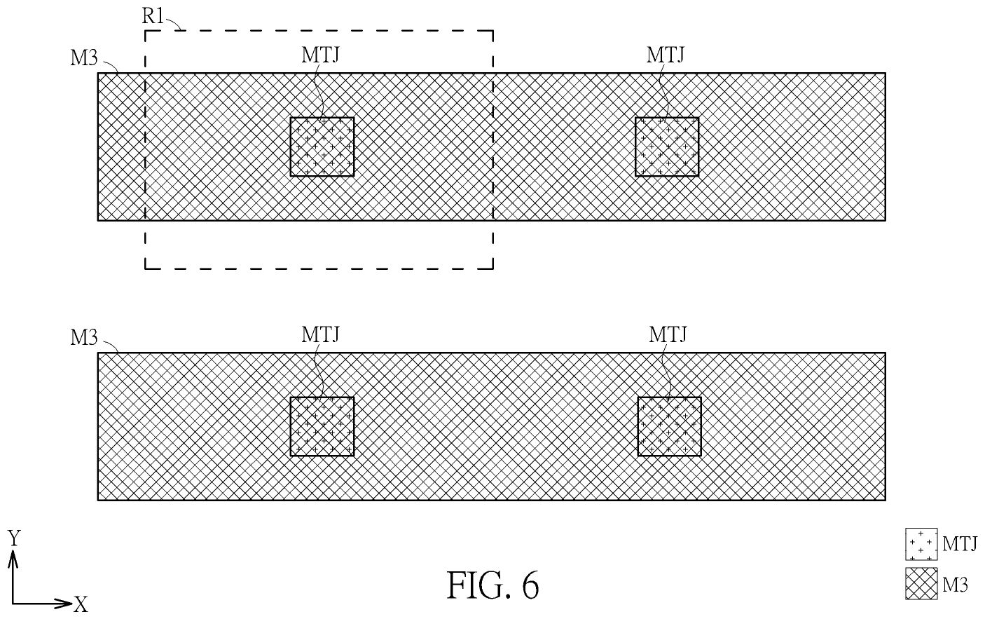

Please refer to FIG. 6, which shows the top view of the MTJ element and the third metal layer in the semiconductor layout of the present invention. As shown in FIG. 6, after the formation of the MTJ element, the third metal layer M3 is formed. The third metal layer M3 extends along the X direction, but the present invention is not limited to this. Subsequently, it is also possible to continue to form other metal plugs or metal layers for connecting the MTJ element and the third metal layer M3 to the bit line.

The layout diagrams shown in FIGS. 2 to 6 above show an MRAM structure including fin structures. Each semiconductor cell, for example, in the region R1, includes two transistors and an MTJ element, so it can also be called a 2T1MTJ element. Under the configuration shown in FIGS. 2 to 6, the layout pattern of the semiconductor structure has the advantages of simplified pattern, high area utilization rate and integrated fin structure, so it can achieve three-dimensional effect.

The above-mentioned region where the MRAM structure is formed can be defined as MRAM region. It is worth noting that, as mentioned above, there are not only MRAM regions, but also high-voltage device regions on the chip, in which the driving voltages of the devices contained in the high-voltage device regions are usually larger (usually greater than 10V). In other words, in the structure shown in the present invention, the high-voltage device region and the MRAM region are located on the same chip, which can achieve the advantages of effectively utilizing the area, improving the operating speed of the wafer, improving the product yield and the like (because MRAM has the characteristics of high operating speed, non-volatility, etc.), but when the high-voltage device in the high-voltage device region operates, it may generate strong electromagnetic waves to affect other surrounding elements, such as the elements in the MRAM region. Therefore, in another embodiment of the present invention, a shielding structure is provided, which is arranged between the MRAM region and the high-voltage device region, so as to shield electromagnetic waves and reduce the influence on elements in the MRAM region.

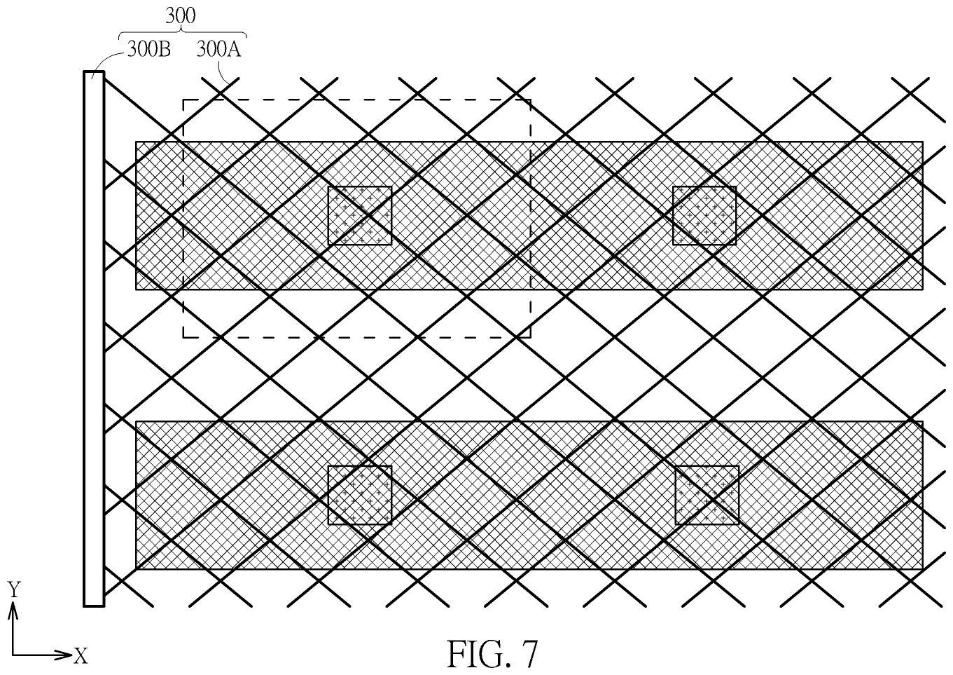

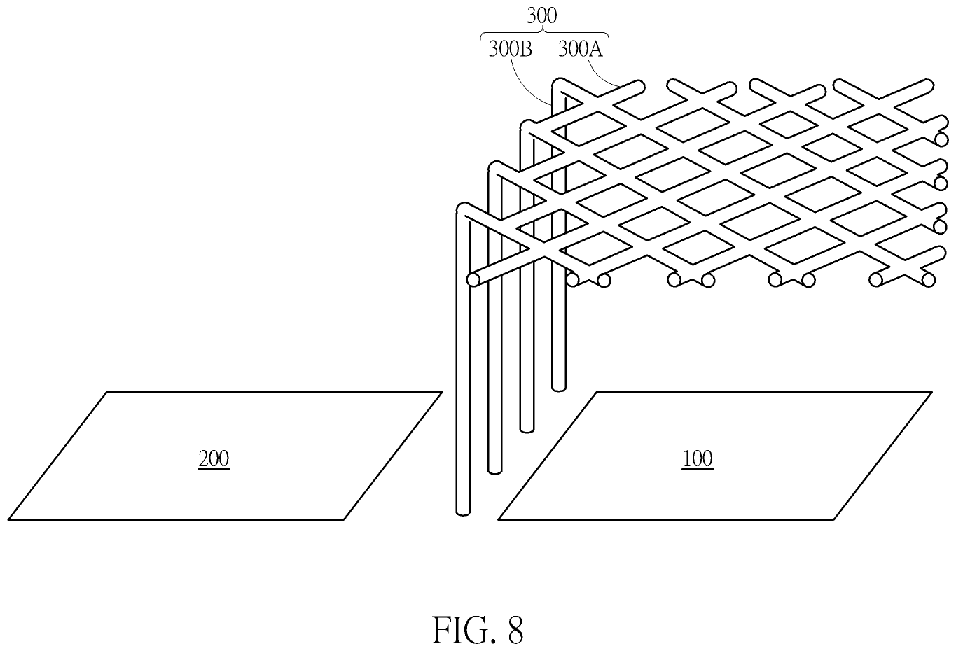

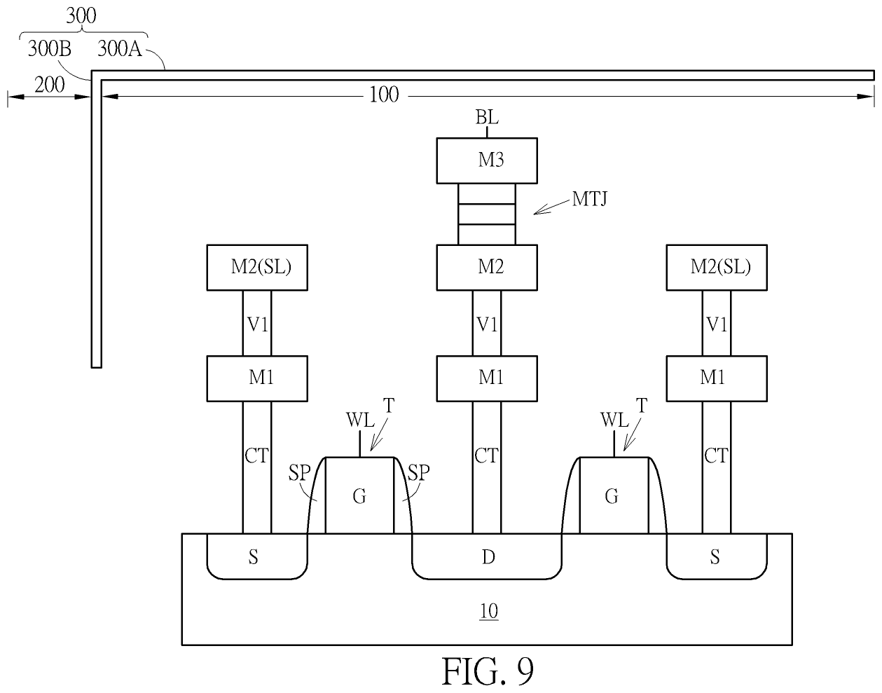

For more details, please refer to FIGS. 7, 8 and 9. FIG. 7 shows a top view of the shielding structure in the semiconductor structure of the present invention, FIG. 8 shows a three-dimensional schematic diagram of the shielding structure in the semiconductor structure of the present invention, and FIG. 9 shows a schematic diagram of the cross-sectional structure of the shielding structure and MRAM structure in the semiconductor structure of the present invention. As shown in FIGS. 7 to 9, the region where the MRAM structure formed in FIG. 6 is located is defined as MRAM region 100, and there is another high-voltage device region 200 beside MRAM region 100, wherein MRAM region 100 is adjacent to high-voltage device region 200. The high-voltage device region 200 contains some high-voltage devices, the driving voltage of which is usually greater than 10 volts, and the high-voltage devices are not shown here for the sake of simplicity. In this embodiment, a shielding structure 300 is included between the MRAM region 100 and the high-voltage device region 200, wherein the shielding structure 300 has a horizontal part 300A and a vertical part 300B. Seen from the top view (FIG. 7), the horizontal part 300A of the shielding structure 300 has a mesh shape, while viewed from the side (FIG. 8), the vertical part 300B of the shielding structure 300 has a fence shape, that is, it contains a plurality of vertical pillars arranged adjacent to each other. It is worth noting that from FIG. 7, although the horizontal part 300A of the shielding structure 300 is formed above the third metal layer M3, it may be formed in a multilayer dielectric layer above the third metal layer M3, for example, it may be formed in the same dielectric layer as the seventh metal layer (commonly referred to as M7 by those skilled in the art). In other words, between the horizontal part 300A of the shielding structure 300 and the third metal layer M3, structures such as the fourth metal layer, the fifth metal layer, the sixth metal layer, and multilayer vertical conductive plugs may be included. The fourth metal layer, the fifth metal layer, the sixth metal layer and the seventh metal layer mentioned here are other metal layers above the third metal layer M3, and their composition materials are similar to those of the first metal layer M1, the second metal layer M2, the third metal layer M3, etc., and other related technologies are known in the field, and they will not be repeated here.

As for the vertical part 300B of the shielding structure 300, it can extend downward from the boundary of the horizontal part 300A, for example, from the dielectric layer where the seventh metal layer is located. Preferably, the bottom surface of the vertical part 300B is lower than the bottom surface of the MTJ element, so that the effect of better protecting the MTJ element can be obtained. For example, the vertical part 300B can extend to the dielectric layer (not shown) where the second metal layer M2 is located or lower.

Based on the above description and drawings, the present invention provides a semiconductor layout pattern including a high-voltage device. The semiconductor layout pattern includes a substrate 10, on which a high-voltage device region 200 and an MRAM (magnetic random access memory) region 100 are adjacent to each other, wherein the MRAM region 100 at least includes a plurality of MRAM cells (the semiconductor cells in the region R1 are regarded as one semiconductor cell or an MRAM cell) arranged in an array. Each MRAM cell includes two fin structures F parallel to each other and arranged along a X direction, two gate structures G parallel to each other and arranged along a Y direction, a drain metal layer MD2 located between the two gate structures G, two source metal layers MD1 located on the other side of the two gate structures G relative to the drain metal layer MD2, and an MTJ (magnetic tunneling junction) element MTJ electrically connected to the drain metal layer MD2.

In some embodiments of the present invention, each MRAM cell further includes a drain contact plug CT2 electrically connected and directly contacting the drain metal layer MD2, and two source contact plugs CT1 electrically connected and directly contacting the source metal layer MD1.

In some embodiments of the present invention, two adjacent MRAM cells in the Y direction share two source contact plugs CT1.

In some embodiments of the present invention, as viewed from the top view, two source contact plugs CT1 shared by two adjacent MRAM cells in the Y direction and two drain contact plugs CT2 contained in two MRAM cells constitute a diamond pattern (as shown in FIGS. 2 and 3).

In some embodiments of the present invention, the two source contact plugs CT1 are aligned in the X direction.

In some embodiments of the present invention, when viewed from the top, the drain contact plug CT2 is located between two parallel fin structures F (as shown in FIG. 2).

In some embodiments of the present invention, a word line WL is further included to electrically connect the two gate structures G.

In some embodiments of the present invention, a selection line SL is further included to electrically connect the two source metal layers MD1.

In some embodiments of the present invention, a bit line BL is further included to electrically connect the drain metal layer MD2.

In some embodiments of the present invention, the MTJ element is located above the drain metal layer MD2 in cross section, and the MTJ element is located in a dielectric layer (i.e., the dielectric layer where the third metal layer M3 is located, which is not drawn for simplicity of the drawing).

In some embodiments of the present invention, a shielding structure 300 is further included. Seen from the cross section, the shielding structure 300 includes a horizontal part 300A and a vertical part 300B, and the horizontal part 300A is located in another dielectric layer above the MTJ element (i.e., the dielectric layer where the seventh metal layer is located, for example, which is not drawn for the sake of simplicity).

In some embodiments of the present invention, the horizontal part 300A of the shielding structure 300 is a mesh when viewed from the top.

In some embodiments of the present invention, the vertical part 300B of the shielding structure 300 extends downward when viewed from the cross section, and a bottom surface of the vertical part 300B is lower than a bottom surface of the MTJ element (as shown in FIG. 9).

In some embodiments of the present invention, the vertical part 300B of the shielding structure 300 is located between the high-voltage device region 200 and the MRAM region 100 when viewed in cross section.

In some embodiments of the present invention, the vertical part 300B of the shielding structure 300 has a fence shape, and includes a plurality of vertically extending pillar structures arranged in parallel with each other.

The present invention also provides a semiconductor structure including high-voltage devices, which comprises a substrate 10, on which a high-voltage device region 200 and an MRAM (magnetic random access memory) region 100 are adjacent to each other, wherein the MRAM region 100 contains a plurality of fin structures F, at least one MTJ (magnetic tunneling junction) element is located on the plurality of fin structures F, and a shielding structure 300, which includes a horizontal part 300A and a vertical part 300B, and the vertical part 300B is located between the high-voltage device region 200 and the MRAM region 100.

In some embodiments of the present invention, the horizontal part 300A of the shielding structure 300 is located above the MTJ (magnetic tunneling junction) element, and the horizontal part 300A and the vertical part 300B are integrally formed.

To sum up, the invention provides a semiconductor layout pattern including a high-voltage device. The invention is characterized in that a high-voltage device region and an MRAM region are integrated on a chip, wherein the MRAM in the MRAM region is suitable for replacing the display memory in the prior art, and has the advantages of non-volatility, high reading and writing speed, low power consumption and the like, and can greatly improve the performance of a display driving chip. In addition, the MRAM region of the present invention further makes the element on the fin structure to form a three-dimensional element, so that the element area can be further reduced and the element density can be improved. However, since the high-voltage device region and the MRAM region are integrated on the same chip at the same time, in order to prevent the high-voltage device from generating strong electromagnetic waves to affect the operation efficiency of the device in the MRAM region, another embodiment of the present invention provides a shielding structure, in which the shielding structure has a special shape (the horizontal part is a mesh and the vertical part is a fence), which has the advantages of shielding electromagnetic waves and improving the product yield.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor layout pattern including a high-voltage device, comprising:
a substrate including a high-voltage device region and a MRAM (magnetic random access memory) region adjacent to each other;
the MRAM region at least comprises a plurality of MRAM cells arranged in an array, wherein each MRAM cell comprises:
two fin structures parallel to each other and arranged along a X direction;
two gate structures parallel to each other and arranged along a Y direction;
a drain metal layer located between the two gate structures;
two source metal layers located on the other side of the two gate structures relative to the drain metal layer; and
an MTJ (magnetic tunneling junction) element electrically connected to the drain metal layer.

2. The semiconductor layout pattern including high-voltage devices according to claim 1, wherein each MRAM cell further comprises a drain contact plug electrically connected and directly contacting the drain metal layer, and two source contact plugs electrically connected and directly contacting the source metal layer.

3. The semiconductor layout pattern including a high-voltage device according to claim 2, wherein two MRAM cells adjacent in the Y direction share the two source contact plugs.

4. The semiconductor layout pattern including a high-voltage device according to claim 3, wherein the two source contact plugs shared by the two adjacent MRAM cells in the Y direction and the drain contact plugs contained in the two MRAM cells constitute a diamond pattern when viewed from the top.

5. The semiconductor layout pattern including a high-voltage device according to claim 2, wherein the two source contact plugs are aligned in the X direction.

6. The semiconductor layout pattern including a high-voltage device according to claim 2, wherein the drain contact plug is located between the two parallel fin structures when viewed from the top.

7. The semiconductor layout pattern including a high-voltage device according to claim 1, further comprising a word line electrically connecting the two gate structures.

8. The semiconductor layout pattern including a high-voltage device according to claim 1, further comprising a selection line electrically connecting the two source metal layers.

9. The semiconductor layout pattern including a high-voltage device according to claim 1, further comprising a bit line electrically connected to the drain metal layer.

10. The semiconductor layout pattern including a high-voltage device according to claim 1, wherein the MTJ element is located above the drain metal layer, and the MTJ element is located in a dielectric layer when viewed from a cross section.

11. The semiconductor layout pattern including high-voltage devices according to claim 10, further comprising a shielding structure, in a cross-sectional view, the shielding structure comprises a horizontal part and a vertical part, and the horizontal part is located in another dielectric layer above the MTJ element.

12. The semiconductor layout pattern including high-voltage devices according to claim 11, wherein the horizontal part of the shielding structure is a mesh when viewed from the top.

13. The semiconductor layout pattern including a high-voltage device according to claim 11, wherein the vertical part of the shielding structure extends downward in a cross-sectional view, and a bottom surface of the vertical part is lower than a bottom surface of the MTJ element.

14. The semiconductor layout pattern including a high-voltage device according to claim 11, wherein the vertical part of the shielding structure is located between the high-voltage device region and the MRAM region when viewed from the cross section.

15. The semiconductor layout pattern including high-voltage devices according to claim 11, wherein the vertical part of the shielding structure has a fence shape, and comprises a plurality of vertically extending pillar structures arranged in parallel with each other.

16. A semiconductor structure including a high-voltage device, comprising:
a substrate, which includes a high-voltage device region and a MRAM (magnetic random access memory) region adjacent to each other, wherein the MRAM region includes a plurality of fin structures, and at least one MTJ (magnetic tunneling junction) element is located on the plurality of fin structures; and
a shielding structure, which includes a horizontal part and a vertical part, and the vertical part is located between the high-voltage device region and the MRAM region.

17. The semiconductor layout pattern including a high-voltage device according to claim 16, wherein the horizontal part of the shielding structure is a mesh when viewed from the top.

18. The semiconductor layout pattern including a high-voltage device according to claim 16, wherein the vertical part of the shielding structure extends downward when viewed from the cross section, and a bottom surface of the vertical structure is lower than a bottom surface of the MTJ element.

19. The semiconductor layout pattern including a high-voltage device according to claim 16, wherein the vertical part of the shielding structure has a fence shape when viewed from a cross section, and comprises a plurality of vertically extending pillar structures arranged in parallel with each other.

20. The semiconductor layout pattern including a high-voltage device according to claim 16, wherein the horizontal part of the shielding structure is located above the MTJ element in a cross-sectional view, and the horizontal part and the vertical part are integrally formed.
